(19) United States
(12) Patent Application Publication
(10) Pub. No.: US 2023/0099777 A1
(43) Pub. Date: Mar. 30, 2023

(54) PRODUCTION APPARATUS FOR PRODUCING STRUCTURAL BODY AND PRODUCTION METHOD FOR PRODUCING STRUCTURAL BODY

(71) Applicants: SCIOCS COMPANY LIMITED, Hitachi-shi (JP); SUMITOMO CHEMICAL COMPANY, LIMITED, Tokyo (JP)

(72) Inventors: Fumimasa HORIKIRI, Hitachi-shi (JP); Noboru FUKUHARA, Hitachi-shi (JP)

(73) Assignees: SCIOCS COMPANY LIMITED, Hitachi-shi (JP); SUMITOMO CHEMICAL COMPANY, LIMITED, Tokyo (JP)

(21) Appl. No.: 17/941,686

(22) Filed: Sep. 9, 2022

(30) Foreign Application Priority Data
Sep. 10, 2021 (JP) 2021-147754

(51) Int. Cl. H01L 21/306; H01L 21/66; H01L 21/67

(52) U.S. Cl. CPC H01L 21/30612; H01L 22/12; H01L 21/67086

(57) ABSTRACT

A production apparatus for producing a structural body includes: a holding mechanism that holds a processing target in contact with an etching solution, the processing target including an etch region that is made of a Group III nitride, and on which photoelectrochemical etching is to be performed; a light emitting device that irradiates the processing target with first light for performing the photoelectrochemical etching; a light emitting device that irradiates the processing target with second light that has a wavelength longer than that of the first light; and a measurement device that measures reflected light resulting from the second light being reflected off a surface of the etch region.

### BACKGROUND OF THE DISCLOSURE

### 1. Technical Field

The present disclosure relates to a production apparatus for producing a structural body and a production method for producing a structural body.

### 2. Description of Related Art

A Group III nitride such as gallium nitride (GaN) is used as a material for producing semiconductor devices such as light emitting elements and transistors.

As an etching technique for forming various structures on a Group III nitride such as GaN, photoelectrochemical (PEC) etching is proposed (see, for example, Non-Patent document 1). PEC etching is preferable because it is wet etching that causes less damage as compared with ordinary dry etching, and an apparatus for performing PEC etching is simpler as compared with an apparatus for special dry etching that causes less damage such as neutral beam etching (see, for example, Non-Patent document 2) or atomic layer etching (see, for example, Non-Patent document 3).
[Non-patent document 1] K. Miwa, Appl. Phys. Express 13, 026508 (2020)
[Non-Patent Document 2] S. Samukawa, JJAP, 45(2006)2395
[Non-Patent Document 3] T. Ohba, Jpn. J. Appl. Phys. 56, 06HB06 (2017)).

### SUMMARY OF THE DISCLOSURE

It is an object of the present disclosure to provide a new measurement technique for enhancing the controllability of PEC etching on a Group III nitride.

An aspect of the present disclosure provides a production apparatus for producing a structural body, the production apparatus including: a holding mechanism that holds a processing target in contact with an etching solution, the processing target including an etch region that is made of a Group III nitride, and on which photoelectrochemical etching is to be performed; a light emitting device that irradiates the processing target with first light for performing the photoelectrochemical etching; a light emitting device that irradiates the processing target with second light that has a wavelength longer than that of the first light; and a measurement device that measures scattered light resulting from the second light being scattered by a surface of the etch region.

Another aspect of the present disclosure provides a production apparatus for producing a structural body, the production apparatus including: a holding mechanism that holds a processing target in contact with an etching solution, the processing target including an etch region in a layer made of a Group III nitride, and on which photoelectrochemical etching is to be performed; a light emitting device that irradiates the processing target with first light for performing the photoelectrochemical etching; a light emitting device that irradiates the processing target with second light that has a wavelength longer than that of the first light; and a measurement device that measures reflected light resulting from the second light being reflected off a surface of the etch region and reflected light resulting from the second light being reflected off a stack interface of the layer.

Yet another aspect of the present disclosure provides a production method for producing a structural body, the production method including: bringing a processing target into contact with an etching solution, the processing target including an etch region that is made of a Group III nitride, and on which photoelectrochemical etching is to be performed; irradiating the processing target with first light for performing the photoelectrochemical etching so as to perform the photoelectrochemical etching on the etch region; and, at the same time, irradiating the processing target with second light that has a wavelength longer than that of the first light for performing the photoelectrochemical etching so as to measure scattered light resulting from the second light being scattered by a surface of the etch region and monitor progress of the photoelectrochemical etching.

Yet another aspect of the present disclosure provides a production method for producing a structural body, the production method including: bringing a processing target into contact with an etching solution, the processing target including an etch region in a layer made of a Group III nitride, and on which photoelectrochemical etching is to be performed; irradiating the processing target with first light for performing the photoelectrochemical etching so as to perform the photoelectrochemical etching on the etch region; and, at the same time, irradiating the processing target with second light that has a wavelength longer than that of the first light for performing the photoelectrochemical etching so as to measure reflected light resulting from the second light being reflected off a surface of the etch region and reflected light resulting from the second light being reflected off a stack interface of the layer and monitor progress of the photoelectrochemical etching.

A new measurement technique for enhancing the controllability of PEC etching on a Group III nitride is provided.

### BRIEF DESCRIPTION OF THE DRAWINGS

FIG. 1 is a schematic diagram showing an example of a configuration of a production apparatus for producing a structural body according to an embodiment of the present disclosure.

FIGS. 2A and 2B are schematic diagrams showing a start time and an end time of PEC etching, respectively.

FIG. 3A is a schematic diagram showing a production method for producing a structural body according to a first embodiment, and FIG. 3B is a schematic diagram showing a production method for producing a structural body according to a second embodiment.

FIG. 4A is a schematic diagram showing a holding mechanism according to another aspect, and FIG. 4B is a schematic diagram showing a holding mechanism according to yet another aspect.

### DETAILED DESCRIPTION OF THE DISCLOSURE

A production apparatus 200 for producing a structural body according to an embodiment of the present disclosure (hereinafter also referred to as an “apparatus 200”), and a production method for producing a structural body performed using the apparatus 200 will be described. A general configuration and operation of the apparatus 200 will be described first, and then, a production method for producing a structural body performed using the apparatus 200 will be described in more detail.

The apparatus 200 is a PEC etching apparatus for performing photoelectrochemical (PEC) etching on a Group III nitride. A feature of the apparatus 200 according to the present embodiment is that the apparatus 200 includes a measurement device 240 for observing an etch region 30.

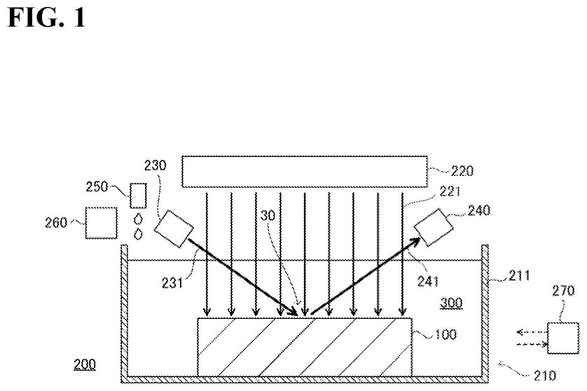

FIG. 1 is a schematic diagram showing an example of a configuration of the apparatus 200. The apparatus 200 in this example includes a holding mechanism 210, a light emitting device 220, a light emitting device 230, the measurement device 240, a supply device 250, a heating device 260, and a control device 270.

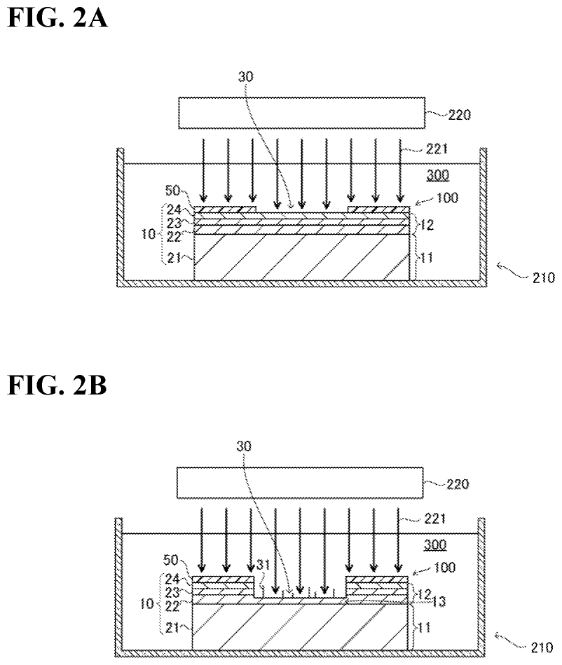

A processing target 100 includes an etch region 30 that is made of a Group III nitride and on which PEC etching is to be performed. The processing target 100 includes an etching target 10 and a mask 50 for defining the etch region 30 (see FIG. 2A and the like).

The holding mechanism 210 holds the processing target 100 in a state in which the processing target 100 is in contact with an etching solution 300 that is used for PEC etching. The holding mechanism 210 shown in FIG. 1 includes a container 211 in which the etching solution 300 is contained. The etching solution 300 is filled to a position higher than the upper surface of the processing target 100 that is placed in the container 211, and the processing target 100 (the etch region 30 defined in the processing target 100) is thereby held in contact with the etching solution 300.

The light emitting device 220 irradiates the processing target 100 with light for performing PEC etching, specifically, excitation light 221 that is light for generating holes in the Group III nitride. The excitation light 221 is emitted from the upper surface side (the surface side) of the processing target 100 to the processing target 100 via the etching solution 300.

The light emitting device 230 irradiates the processing target 100 (a measurement region that is defined in at least a portion of the etch region 30) with measurement light 231 that has a wavelength longer than that of the excitation light 221 and does not generate holes in the Group III nitride that is subjected to the PEC etching. The light emitting device 230 irradiates the processing target 100 with the measurement light 231 from the upper surface side (the surface side) of the processing target 100, or in other words, from the surface side that is the same as the surface that is irradiated with the excitation light 221.

The light emitting device 230 may include, where necessary, a moving mechanism (scanning mechanism) that moves a constituent member of the light emitting device 230 such that a predetermined measurement region can be observed. Also, the light emitting device 230 may include, where necessary, an optical system (a mirror, a lens, and the like) between a light source of the light emitting device 230 and the processing target 100.

The measurement device 240 measures observation light 241 that is light resulting from the measurement light 231 being reflected off the surface (measurement region) of the etch region 30. The measurement device 240 includes an optical sensor that the observation light 241 enters, and measures the intensity (and wavelength where necessary) of the observation light 241. The measurement device 240 may include, where necessary, a moving mechanism (scanning mechanism) that moves a constituent member of the measurement device 240 such that a predetermined measurement region can be observed. Also, the measurement device 240 may include, where necessary, an optical system (a mirror, a lens, and the like) that guides the observation light 241 to the optical sensor.

The supply device 250 supplies the etching solution 300. As will be described later in detail, the etching solution 300 preferably contains peroxydisulfuric acid ions, and is used in PEC etching in a state in which sulfate ion radicals have been generated from the peroxydisulfuric acid ions through heating or light irradiation.

The heating device 260 is used to generate radicals through heating. The heating device 260 may be a device configured to heat the etching solution 300 before the etching solution 300 is supplied (discharged) from the supply device 250, or a device configured to heat the etching solution 300 after the etching solution 300 has been supplied (discharged) from the supply device 250. In the case where radicals are generated through light irradiation, for example, the excitation light 221 may have a wavelength (200 nm or more and less than 310 nm) suitable for radical generation, or, for example, a light source for radical generation that emits light that has the above-described wavelength may be used separately.

The control device 270 controls various devices that are included in the apparatus 200 such that predetermined operations are performed at predetermined timings. Also, the control device 270 performs various kinds of analysis processing based on data output from the optical sensor of the measurement device 240. The control device 270 may be considered as a part of the measurement device 240. The control device 270 may be configured using, for example, a personal computer.

In a production method for producing a structural body performed using the apparatus 200 according to the embodiment, the processing target 100 is brought into contact with the etching solution 300, the processing target 100 is irradiated with the excitation light 221 for performing PEC etching (for generating holes in the Group III nitride) so as to perform PEC etching on the etch region 30, and at the same time, the processing target 100 is irradiated with the measurement light 231 that has a wavelength longer than that of the excitation light 221 (that does not generate holes in the Group III nitride). Then, the etch region 30 is observed using the observation light 241 generated from the measurement light 231 to monitor the progress of the PEC etching.

PEC etching will be described. First, the mechanism of PEC etching will be described. An example will be described in which gallium nitride (GaN) is used as an example of the Group III nitride that is subjected to the PEC etching.

PEC etching is wet etching, and is performed in a state in which the processing target 100 is in contact with the etching solution 300. As the etching solution 300, an alkaline or acidic etching solution 300 that contains oxygen that is used to generate an oxide of a Group III element that is contained in the Group III nitride that constitutes the etch region 30 and also contains an oxidizing agent that receives electrons is used.

As the oxidizing agent, peroxydisulfuric acid ions (S₂O₈²⁻) are preferably used. As the etching solution 300, an aqueous solution obtained by dissolving (at least) a salt of peroxydisulfuric acid ions (S₂O₈²⁻) in water at a predetermined concentration is used. More specifically, the oxidizing agent functions such that sulfate ion radicals (SO₄^{-*}) generated from S₂O₈²⁻ receive electrons and transform into sulfate ions (SO₄²⁻).

As the salt of S₂O₈²⁻ used in the etching solution 300, for example, ammonium peroxodisulfate (NH₄)₂S₂O₈, potassium peroxodisulfate (K₂S₂O₈), sodium peroxodisulfate (Na₂S₂O₈), and the like can be used. From the viewpoint of suppressing alkali metal element residues produced by the etching solution 300, it is preferable to use (NH₄)₂S₂O₈ that does not contain alkali metal. Aqueous solutions prepared using these salts of S₂O₈²⁻ are all acidic. For example, an alkaline etching solution used as the etching solution 300 can also be obtained by mixing any of the aqueous solutions prepared using the salts of S₂O₈²⁻ with an alkaline aqueous solution such as an aqueous solution of potassium hydroxide (KOH) at an appropriate concentration.

The reaction that takes place in PEC etching can be expressed by [Chemical formula 1].

$$GaN ( s ) + photocarriers ( 3 {h}^{+} + 3 {e}^{-} ) 3 {SO}_{4}^{- *} + \frac{3}{2} {H}_{2} O ( 1 ) \to \frac{1}{2} {Ga}_{2} {O}_{3} ( s ) + 3 {H}^{+} + 3 {SO}_{1}^{2 -} + \frac{1}{2} {N}_{2} ( g ) ↑ \qquad [ Chemical formula 1 ]$$

The reaction that generates SO₄^{-*} from S₂O₈²⁻ contained in the etching solution can be expressed by [Chemical formula 2]. That is, SO₄^{-*} can be generated by at least one of heating S₂O₈²⁻ and irradiating S₂O₈²⁻.

S₂O₈²⁻+heat or hv→2SO₄^{-*} [Chemical formula 2]

As shown in [Chemical formula 1], by irradiating a Group III nitride with the excitation light 221 that has a wavelength less than or equal to a wavelength that corresponds to the band gap of the Group III nitride (in this example, ultraviolet light that has a wavelength of 365 nm or less that corresponds to the band gap of GaN), holes (h⁺) and electrons (e⁻) are generated in the Group III nitride. As a result of holes being generated, the Group III nitride (in this example, GaN) is decomposed into positive ions of the Group III element (in this example, Ga³⁺) and nitrogen gas (N₂ gas), the positive ions of the Group III element bond to oxygen that is contained in water (H₂O), and an oxide of the Group III element (in this example, Ga₂O₃) is generated. The oxide of the Group III element is dissolved in an alkaline or acidic etching solution serving as the etching solution 300, and the Group III nitride is thereby etched. The electrons generated in the Group III nitride are consumed by being bonded to SO₄^{-*} to generate SO₄²⁻.

In the case where a resist mask is used as the mask 50, it is preferable to use an acidic etching solution as the etching solution 300. The mask 50 may be made of a combination of a non-conductive material such as a resist material and a conductive material such as a metal (such that the mask 50 includes both a portion made of the non-conductive material and a portion made of the conductive material when viewed in a plan view). The mask 50 made of the conductive material functions as a cathode (a cathode pad) that releases electrons generated and paired with the holes to the etching solution 300.

As a result of the etching solution 300 containing the oxidizing agent (S₂O₈²⁻), PEC etching can be performed in a (contactless) manner in which electrons are released from the processing target 100 directly into the etching solution 300 (without connection to an external lead wire). It is also possible to perform PEC etching in a (contact) manner in which electrons are released due to connection to an external lead wire. The technique for observing the etch region 30 according to the present embodiment is applicable not only to the (contactless) PEC etching without connection to a lead wire, but also to the (contact) PEC etching due to connection to a lead wire.

PEC etching can also be performed on a Group III nitride other than GaN used as an example. The Group III nitride may contain at least one Group III element selected from aluminum (Al), gallium (Ga), and indium (In). The concept of PEC etching performed on an Al component or an In component contained in the Group III nitride is the same as that of the PEC etching performed on the Ga component described with reference to [Chemical formula 1]. That is, PEC etching can be performed by irradiating the Group III nitride with light to generate holes so as to form an oxide of Al or an oxide of In, and dissolving the resulting oxide in an alkaline or acidic etching solution. The wavelength of the emitted excitation light 221 may be changed as appropriate according to the composition of the Group III nitride that is subjected to the etching. In the case where the Group III nitride contains Al, excitation light 221 with a shorter wavelength may be used, and in the case where the Group III nitride contains In, excitation light 221 with a longer wavelength may be used relative to the PEC etching performed on GaN. That is, the excitation light 221 with a wavelength at which the Group III nitride can be photoelectrochemically etched may be selected and used as appropriate according to the composition of the Group III nitride that is to be etched.

Next, a more specific aspect of PEC etching will be described. FIGS. 2A and 2B are schematic diagrams showing a start time and an end time of PEC etching, respectively.

The processing target 100 includes an etching target 10 and a mask 50. The etching target 10 is a substrate (wafer) on which PEC etching is to be performed. The mask 50 is placed on the upper surface of the etching target 10 and defines the etch region 30 on which PEC etching is to be performed. The mask 50 may be made of a non-conductive material such as, for example, a resist material, or a conductive material such as, for example, a metal. Furthermore, the mask 50 may be made of a combination of a non-conductive material and a conductive material. The processing target 100 may be configured such that the entire upper surface is to be photoelectrochemically etched, or in other words, the entire upper surface is the etch region 30 (no mask 50 present).

The etching target 10 includes an underlying layer 11 and an etching target layer 12. The etching target layer 12 is made of a Group III nitride, and the etch region 30 is defined in the etching target layer 12. The underlying layer 11 is a thick portion that is located under the etching target layer 12 and is not subjected to PEC etching. The underlying layer 11 may be made of a Group III nitride or a different material other than a Group III nitride.

The difference between the thickness of the etching target layer 12 (before PEC etching) and a remaining etching portion 13 of the etching target layer 12 is defined as the etching depth resulting from the PEC etching. Accordingly, by measuring the thickness of the remaining etching portion 13 (in situ) at the same time as when the PEC etching is being performed, the etching depth can be measured (in situ) at the same time as when PEC etching is being performed.

The upper surface of the etching target 10, or in other words, an etch surface on which PEC etching is to be performed is formed by the c-plane of the Group III nitride. As used herein, the expression “formed by the c-plane” means that a low-index crystal plane closest to the upper surface is the c-plane of the crystal of the Group III nitride that constitutes the etching target layer 12. The Group III nitride that constitutes the etching target layer 12 includes dislocations (threading dislocations), and the dislocations are distributed in the upper surface at a predetermined density.

In the dislocations, the lifetime of holes is short, and thus PEC etching is unlikely to occur. Accordingly, projections 31 are likely to be formed at the bottom of a cavity formed through PEC etching, or in other words, the surface of the etch region 30, at positions that correspond to the dislocations, as portions that remain undissolved after the PEC etching.

The height of a projection 31 tends to increase as the PEC etching proceeds. Accordingly, the surface roughness of the etch region 30 tends to be increase (become rougher) as the PEC etching proceeds, or in other words, the etching depth resulting from the PEC etching becomes deeper. The surface roughness of the etch region 30 may become large (rough) due to increased variation in the etching depth within the plane as the PEC etching proceeds.

Hereinafter, first and second embodiments will be described as more specific aspects. In the first and second embodiments, an epitaxial substrate that has a stack structure that constitutes a high-electron-mobility transistor (HEMT) is used as the etching target 10. An example of an aspect will be described in which an element isolation groove is formed in the above-described etching target 10 through PEC etching. The processing target 100 includes an etching target 10 and a mask 50 that has an opening in a region where an element isolation groove is to be formed.

The etching target layer 12 in this example includes a channel layer 22 made of GaN, a barrier layer 23 made of aluminum gallium nitride (AlGaN), and a cap layer 24 made of GaN. A two-dimensional electron gas (2DEG) that serves as a channel of the HEMT is formed in the vicinity of the upper surface of the channel layer 22. An element isolation groove is formed by forming a cavity that extends from the upper surface of the cap layer 24 to a depth midway of the channel layer 22 (a depth that divides the 2DEG) through PEC etching.

The underlying layer 11 is, for example, a GaN substrate 21, and functions as a base substrate for epitaxially growing the etching target layer 12. The underlying layer 11 may have another configuration where necessary. For example, the underlying layer 11 may be obtained by forming an intermediate layer (a nucleation layer or the like) formed of a Group III nitride on a substrate made of a different material (a sapphire substrate, a silicon carbide substrate, a silicon substrate, or the like).

The etching target 10 on which PEC etching is to be performed, and the purpose of the PEC etching are not limited to the examples given above. For example, a gate recess may be formed in the etching target 10 that is an epitaxial substrate for forming an HEMT through PEC etching, and a source recess and a drain recess may also be formed. Also, for example, the etching target 10 may be an epitaxial substrate for forming another semiconductor element (a light emitting element or the like). The area and the (final) etching depth of the etch region 30 may vary according to the purpose of the PEC etching.

### First Embodiment

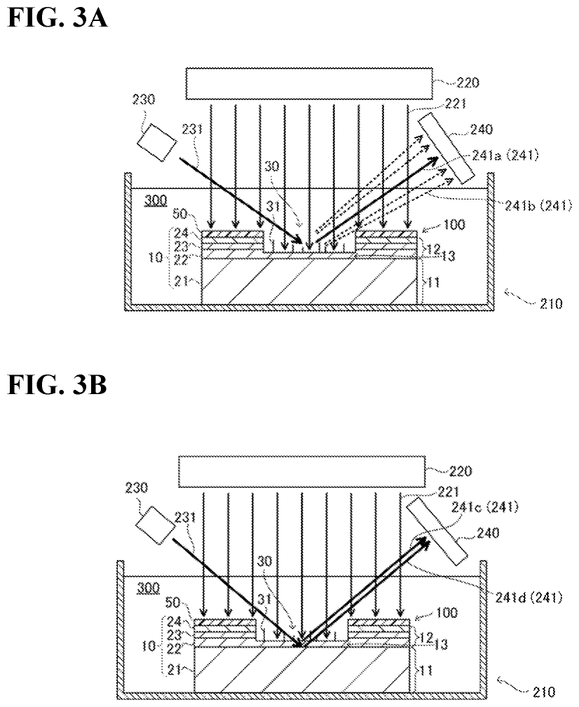

A production method for producing a structural body according to a first embodiment will be described with reference to FIG. 3A. In the first embodiment, scattered light resulting from measurement light 231 being scattered by the surface of the etch region 30 is measured as the observation light 241. The observation light 241 includes a component (specular reflected light) 241a resulting from the measurement light 231 being mirror reflected off the surface of the etch region 30 and a component (scatter reflected light) 241b resulting from the measurement light 231 being scatter reflected off the surface of the etch region 30.

As described above, the surface roughness of the etch region 30 increases as PEC etching proceeds. The degree of scattering of the observation light 241 increases as the surface roughness of the etch region 30 increases (becomes rougher). That is, there is a correlation between the surface roughness of the etch region 30 and the intensity of the scatter reflected light (scattered light) 241b (the relative intensity of the intensity of the scatter reflected light 241b relative to the intensity of the specular reflected light 241a) (hereinafter, this correlation will also be referred to as the correlation between surface roughness and scattered light). Also, there is a correlation between the etching depth resulting from PEC etching and the intensity of the scatter reflected light (scattered light) 241b (the relative intensity of the intensity of the scatter reflected light 241b relative to the intensity of the specular reflected light 241a) (hereinafter, this correlation will also be referred to as the correlation between etching depth and scattered light).

Accordingly, by measuring the intensity of the scatter reflected light 241b, it is possible to measure the surface roughness of the etch region 30 and also measure the etching depth resulting from PEC etching (or the thickness of the remaining etching portion 13). The correlation between surface roughness and scattered light and the correlation between etching depth and scattered light can be acquired in advance through a preparatory experiment, a simulation, or the like.

From the viewpoint of reducing the effect on the PEC etching, the wavelength of the observation light 241, or in other words, the wavelength of the measurement light 231 is preferably set to a long wavelength (a wavelength longer than that of the excitation light 221) at which holes are not generated in the Group III nitride that constitutes the etching target layer 12. The wavelength of the measurement light 231 may be set to, for example, a wavelength in the visible range or, for example, a wavelength in the ultraviolet range. The wavelength, intensity, and the like of the measurement light 231 may be set through a preparatory experiment, a simulation, or the like such that measurement can be performed appropriately.

In the present embodiment, the etching depth is measured by measuring the scatter reflected light (scattered light) 241b while PEC etching is being performed. When the etching depth reaches a predetermined depth appropriate as an element isolation groove (or in other words, when the thickness of the remaining etching portion 13 reaches a thickness that is thinner than the total thickness of the channel layer 22 and corresponds to the predetermined depth), the PEC etching is ended.

In the present embodiment, the etching depth can be monitored (in situ) while PEC etching is being performed. Accordingly, it is possible to control the etching depth (detect the end of the PEC etching) more reliably as compared with the case where the PEC etching is simply time controlled.

The surface roughness of the etch region 30 may be measured. For example, the surface roughness of the etch region 30 may be used in the following manner: when an abnormal surface roughness value (a value of surface roughness greater than or equal to a permitted value) is detected during PEC etching, an inspection is performed on the apparatus 200.

### Second Embodiment

A production method for producing a structural body according to a second embodiment will be described with reference to FIG. 3B. In the second embodiment, as the observation light 241, at least reflected light resulting from measurement light 231 being reflected off the surface of the etch region 30 and reflected light resulting from the measurement light 231 being reflected off a stack interface between an outermost layer on which PEC etching is being performed and a layer immediately under the outermost layer are measured.

The etching target layer 12 has a monolayer structure or a stack structure that contains a Group III nitride, and the thickness of each layer is measured using a Fourier-transform infrared spectroscopy method (FT-IR method), an infrared spectroscopic ellipsometry method, or an ultraviolet spectroscopic ellipsometry method (see, for example, JP 2019-009329A, JP 2019-199373, and the like).

In the measurement method of the present embodiment, the thickness of each layer is determined based on the shape of an interference pattern (fringe pattern) between reflected light beams reflected off the stack interference of each layer, or in other words, the frequency dependence of the intensities of the light beams that have interfered with each other. The light emitting device 230 emits measurement light 231 such that a frequency range used in this measurement is scanned, and an interference pattern of observation light 241 resulting from the measurement light 231 being reflected off the etching target 10 is measured. Here, from the viewpoint of reducing the effect on the PEC etching, the wavelength of the measurement light 231 is preferably set to a long wavelength (a wavelength longer than that of the excitation light 221) at which holes are not generated in the Group III nitride that constitutes the etching target layer 12.

In the present embodiment, in particular, the thickness of the uppermost layer, or in other words, the thickness of a layer that constitutes the surface of the etch region 30 is measured at points in time during PEC etching while the PEC etching is being performed. The thickness of the layer is measured by measuring at least reflected light resulting from the measurement light 231 being reflected off the surface of the etch region 30 (the surface of the layer) and reflected light resulting from the measurement light 231 being reflected off the stack interface between the layer and a layer immediately thereunder (by measuring an interference pattern between these reflected light beams). The etching depth is measured by calculating the thickness of the remaining etching portion 13 of the etching target layer 12 based on the thickness of the layer (the uppermost layer of the etching target layer 12 on which the PEC etching is being performed).

In this example, the etching target 10 has a stack structure that includes a GaN substrate 21, a channel layer (GaN layer) 22, a barrier layer (AlGaN layer) 23, and a cap layer (GaN layer) 24. An element isolation groove is formed by forming a cavity that extends from the upper surface of the cap layer 24 to a depth midway of the channel layer 22 through PEC etching.

During a period in which the cap layer 24 is etched, the thickness of the cap layer 24 is measured using a structure in which the cap layer 24 is stacked on stacked layers composed of the GaN substrate 21, the channel layer 22, and the barrier layer 23 as an optical model.

After the entire thickness of the cap layer 24 has been etched (after the thickness of the cap layer 24 has reached zero), next, the thickness of the barrier layer 23 is measured using a structure in which the barrier layer 23 is stacked on stacked layers composed of the GaN substrate 21 and the channel layer 22 as an optical model during a period in which the barrier layer 23 is etched.

After the entire thickness of the barrier layer 23 has been etched, (after the thickness of the barrier layer 23 has reached zero), next, the thickness of the channel layer 22 is measured using a structure in which the channel layer 22 is stacked on the GaN substrate 21 as an optical model during a period in which the channel layer 22 is etched.

FIG. 3B shows, as an example, reflected light 241c resulting from the measurement light 231 being reflected off the surface of the etch region 30 (the surface of the channel layer 22) and reflected light 241d resulting from the measurement light 231 being reflected off the stack interface of the channel layer 22 (the stack interface between the channel layer 22 and the GaN substrate 21 that is a layer immediately under the channel layer 22) during the period in which the channel layer 22 is etched.

In this example, for measuring the thickness of a thin layer such as the cap layer 24 or the barrier layer 23, an ultraviolet spectroscopic ellipsometry method that uses a relatively short wavelength may be used. For measuring the thickness of the channel layer 22 that is thicker than the cap layer 24 and the barrier layer 23, an FT-IR method or an infrared spectroscopic ellipsometry method that uses relatively a long wavelength may be used. That is, the measurement methods may be combined such that the ultraviolet spectroscopic ellipsometry method is used to measure the thickness of the cap layer 24 and the thickness of the barrier layer 23, and the FT-IR method or the infrared spectroscopic ellipsometry method is used to measure the thickness of the channel layer 22.

As described above, the thickness of a layer (the uppermost layer) that constitutes the surface of the etch region 30 can be measured at points in time during PEC etching by sequentially applying optical models that include different numbers of stacked layers to the processing target 100 (the etching target 10) that has a stack structure that contains a Group III nitride along with the progress of the PEC etching. The composition of each layer and values such as impurity concentration that are used in an optical model may be set based on design values for forming a film or results obtained by subjecting a sample produced under the same conditions to analysis such as secondary ion mass spectrometry or the like.

In this example, when the thickness of the remaining etching portion 13 of the etching target layer 12 reaches a predetermined thickness smaller than the entire thickness of the channel layer 22 (when the etching depth reaches a depth that corresponds to the predetermined thickness), the PEC etching is ended.

In the present embodiment, the thickness of the remaining etching portion 13, or in other words, the etching depth can be monitored (in situ) while PEC etching is being performed. Accordingly, it is possible to control the etching depth (detect the end of the PEC etching) more reliably as compared with the case where the PEC etching is simply time controlled.

Where necessary, the measurement according to the first embodiment and the measurement according to the second embodiment may be performed simultaneously. That is, the light emitting device 230 may be configured to include both a light emitting device for the measurement according to the first embodiment and a light emitting device for the measurement according to the second embodiment. Also, the measurement device 240 may be configured to include both a measurement device (optical sensor) for the measurement according to the first embodiment and a measurement device (optical sensor) for the measurement according to the second embodiment. Different optical paths may be set as an optical path for the measurement according to the first embodiment and an optical path for the measurement according to the second embodiment.

### Other Embodiments

Up to here, the embodiments of the present disclosure have been described specifically. However, the present disclosure is not limited to the embodiments given above, and various modifications, improvements, combinations, and the like may be made within the range that does not depart from the gist of the present disclosure.

As the observation light 241, as will be described below, fluorescent light resulting from the excitation light 221 may be used. As a result of the processing target 100 being irradiated with the excitation light 221, the Group III nitride that constitutes the etching target layer 12 releases fluorescent light that corresponds to a level resulting from carbon entrained in the Group III nitride, voids of the Group III element, and the like. The characteristics (shape) of the emission spectrum of fluorescent light vary at points in time during PEC etching according to the quality (composition, crystalline state, and the like) of the Group III nitride that constitutes the surface (fluorescent light releasing portion) of the etch region 30.

As a result, the characteristics of the emission spectrum of fluorescent light vary according to the etching depth (depending on the layer on which etching is being performed) when PEC etching is performed on the etching target layer 12 (the etching target layer 12 typically having a stack structure composed of a plurality of layers of different compositions) in which the composition of the Group III nitride, growth conditions, and the like vary in the depth direction. Accordingly, by measuring the intensity, peak wavelength, and the like of fluorescent light, it is possible to monitor the etching depth at points in time during the measurement (it is possible to monitor which layer is currently being etched at points in time during the measurement).

The measurement that uses fluorescent light as described above may be performed in combination with each of the first and second embodiments. That is, each of the measurement according to the first embodiment and the measurement according to the second embodiment may be performed while determining, based on the fluorescent light, which layer is currently being etched. In this aspect, the measurement device 240 may be configured to further include a measurement device (optical sensor) for the fluorescent light measurement. An optical path for the fluorescent light measurement may differ from the optical paths for the measurements according to the first and second embodiments.

For example, the measurement that uses fluorescent light as described above may be performed in combination with the second embodiment in the manner described below. First, yellow fluorescent light released from GaN is observed during a period in which the cap layer 24 or in other words, the GaN layer is etched. After the entire thickness of the cap layer 24 has been removed, (dark) fluorescent light that is released from AlGaN and has an intensity weaker than that of GaN is observed during a period in which the barrier layer 23, or in other words, the AlGaN layer is etched. Furthermore, after the entire thickness of the barrier layer 23 has been removed, (bright) fluorescent light that is released from GaN and has an intensity stronger than that of AlGaN is observed during a period in which the channel layer 22, or in other words, the GaN layer is etched. By using the fluorescent light measurement as described above, it can be detected that the channel layer 22 has been reached through the PEC etching.

Then, during a period in which the channel layer 22 is etched, the thickness of the channel layer 22 is measured using an FT-IR method or an infrared spectroscopic ellipsometry method, and when the thickness of the channel layer 22 reaches a predetermined thickness, the PEC etching is ended.

The apparatus 200 may also function as a post-processing apparatus that performs post-processing on the processing target 100 after the PEC etching by replacing the etching solution 300 used as the treatment solution with another liquid (a post-treatment solution). The post-processing may be, for example, planarization etching.

The planarization etching is etching for removing the projections 31 (reducing the heights of the projection 31). As the post-treatment solution (planarization etching solution) used in the planarization etching, for example, the following solutions can be used: an aqueous solution of hydrochloric acid (HCl), a mixed aqueous solution (hydrochloric acid hydrogen peroxide solution) of hydrochloric acid (HCl) and hydrogen peroxide (H₂O₂), a mixed aqueous solution (piranha solution) of sulfuric acid (H₂SO₄) and hydrogen peroxide (H₂O₂), an aqueous solution of tetramethylammonium hydroxide (TMAH), an aqueous solution of hydrogen fluoride (hydrofluoric acid), an aqueous solution of potassium hydroxide (KOH), and the like. More specifically, in the planarization etching, for example, etching is performed for 10 minutes using a hydrochloric acid hydrogen peroxide solution obtained by mixing 30% HCl and 30% H₂O₂ at a ratio of 1:1. In the planarization etching, there is no need to irradiate the processing target 100 with the excitation light 221. After the planarization etching, as additional post-processing, washing processing that uses, for example, water as a treatment solution may be performed.

In the planarization etching, as described in the first embodiment, the surface roughness of the etch region 30 may be measured by measuring the scatter reflected light (scattered light) 24 lb. In this case, the planarization etching may be ended after it has been confirmed that the surface roughness of the etch region 30 has reached a predetermined roughness or less.

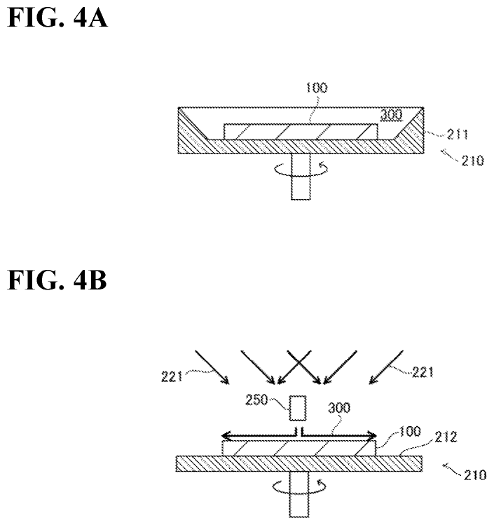

As shown in FIG. 4A, the treatment solution (the etching solution 300 or the post-treatment solution) can be discharged by rotating the container 211 of the holding mechanism 210 to disperse the treatment solution toward the outer peripheral side of the container 211. In this aspect, in order to facilitate the dispersion of the treatment solution toward the outer circumferential side, the inner surface of the container 211 is preferably inclined so as to expand in the upward direction.

FIG. 4B is a schematic diagram showing a holding mechanism 210 according to yet another aspect. In the embodiments given above, the holding mechanism 210 configured to hold the processing target 100 in a state in which the processing target 100 is in contact with the etching solution (treatment solution) 300 by containing the etching solution 300 in the container was shown as an example. A holding mechanism 210 according to an aspect shown in FIG. 4B is configured to hold the processing target 100 in a state in which the processing target 100 is in contact with the etching solution 300 by rotating the processing target 100 held on a holding stage 212 while the etching solution 300 (treatment solution) is continuously supplied from the supply device 250 onto the processing target 100 (the etching solution 300 is spread onto the upper surface of the processing target 100).

The excitation light 221 does not necessarily need to be emitted perpendicularly to the upper surface of the processing target 100. For example, in the PEC etching according to the aspect shown in FIG. 4B, the excitation light 221 may be emitted obliquely to the upper surface of the processing target 100. Furthermore, in this aspect, the excitation light 221 may be emitted obliquely to the upper surface of the processing target 100 from a plurality of directions.

Preferred Aspects of the Present Disclosure

Hereinafter, preferred aspects of the present disclosure will be supplementarily described.

Supplementary Description 1

A production apparatus for producing a structural body, the production apparatus including:

a holding mechanism that holds a processing target in contact with an etching solution, the processing target including an etch region that is made of a Group III nitride, and on which photoelectrochemical etching is to be performed;

a light emitting device that irradiates the processing target with first light for performing the photoelectrochemical etching (for generating holes in the Group III nitride);

a light emitting device that irradiates the processing target with second light that has a wavelength longer than that of the first light (that does not generate holes in the Group III nitride); and

a measurement device that measures scattered light resulting from the second light being scattered by a surface of the etch region.

Supplementary Description 2

A production apparatus for producing a structural body, the production apparatus including:

a holding mechanism that holds a processing target in contact with an etching solution, the processing target including an etch region in a layer made of a Group III nitride, and on which photoelectrochemical etching is to be performed;

a light emitting device that irradiates the processing target with first light for performing the photoelectrochemical etching (for generating holes in the Group III nitride);

a light emitting device that irradiates the processing target with second light that has a wavelength longer than that of the first light (that does not generate holes in the Group III nitride); and

a measurement device that measures reflected light resulting from the second light being reflected off a surface of the etch region and reflected light resulting from the second light being reflected off a stack interface of the layer.

Supplementary Description 3

A production method for producing a structural body, the production method including:

bringing a processing target into contact with an etching solution, the processing target including an etch region that is made of a Group III nitride, and on which photoelectrochemical etching is to be performed;

irradiating the processing target with first light for performing the photoelectrochemical etching (for generating holes in the Group III nitride) so as to perform the photoelectrochemical etching on the etch region; and, at the same time,

irradiating the processing target with second light that has a wavelength longer than that of the first light for performing the photoelectrochemical etching (that does not generate holes in the Group III nitride) so as to measure scattered light resulting from the second light being scattered by a surface of the etch region and monitor progress of the photoelectrochemical etching.

Supplementary Description 4

The production method for producing a structural body according to supplementary description 3,

wherein an etching depth is measured based on a pre-acquired correlation between the etching depth and an intensity of the scattered light and a measured intensity of the scattered light at the same time as when the photoelectrochemical etching is being performed.

Supplementary Description 5

A production method for producing a structural body, the production method including:

bringing a processing target into contact with an etching solution, the processing target including an etch region in a layer made of a Group III nitride, and on which photoelectrochemical etching is to be performed;

irradiating the processing target with first light for performing the photoelectrochemical etching (for generating holes in the Group III nitride) so as to perform the photoelectrochemical etching on the etch region; and, at the same time,

irradiating the processing target with second light that has a wavelength longer than that of the first light for performing the photoelectrochemical etching (that does not generate holes in the Group III nitride) so as to measure reflected light resulting from the second light being reflected off a surface of the etch region and reflected light resulting from the second light being reflected off a stack interface of the layer and monitor progress of the photoelectrochemical etching.

Supplementary Description 6

The production method for producing a structural body according to supplementary description 5,

wherein an etching depth is measured by calculating a thickness of the layer based on the reflected light resulting from the second light being reflected off the surface of the etch region and the reflected light resulting from the second light being reflected off the stack interface of the layer at the same time as when the photoelectrochemical etching is being performed.

Supplementary Description 7

The production method for producing a structural body according to supplementary description 6,

wherein the processing target has a stack structure that contains a Group III nitride, and

a thickness of an uppermost layer of the stack structure is measured at points in time during the photoelectrochemical etching by sequentially applying optical models that include different numbers of stacked layers as the photoelectrochemical etching progresses, the optical models being optical models based on a Fourier-transform infrared spectroscopy method, an infrared spectroscopic ellipsometry method, or an ultraviolet spectroscopic ellipsometry method.

Supplementary Description 8

The production apparatus for producing a structural body according to supplementary description 1 or 2,

wherein the measurement device also measures fluorescent light that is released from the etch region as a result of the processing target being irradiated with the first light.

Supplementary Description 9

The production method for producing a structural body according to any one of Supplementary description 3 to 7,

wherein the progress of the photoelectrochemical etching is monitored by also measuring fluorescent light that is released from the etch region as a result of the processing target being irradiated with the first light.

Supplementary Description 10

The production method for producing a structural body according to supplementary description 9,

wherein the processing target has a stack structure that contains a Group III nitride, and

the production method includes detecting, based on the fluorescent light, which layer in the stack structure is currently being subjected to the photoelectrochemical etching (measuring an etching depth).

### LIST OF REFERENCE NUMERALS

10 Etching target
11 Underlying layer
12 Etching target layer
13 Remaining etching portion
21 GaN substrate
22 Channel layer
23 Barrier layer
24 Cap layer
30 Etch region
31 Projection
50 Mask
100 Processing target
200 Production apparatus for producing structural body
210 Holding mechanism
211 Container
212 Holding stage
220 Light emitting device
221 Excitation light
230 Light emitting device
231 Measurement light
240 Measurement device
241 Observation light
241a Specular reflected light
241b Scatter reflected light
241c Reflected light resulting from measurement light being reflected off surface of etch
region
241d Reflected light resulting from measurement light being reflected off stack interface
250 Supply device
260 Heating device
270 Control device
300 Etching solution (Treatment solution)

What is claimed is:

1. A production apparatus for producing a structural body, the production apparatus comprising:
a holding mechanism that holds a processing target in contact with an etching solution, the processing target including an etch region that is made of a Group III nitride, and on which photoelectrochemical etching is to be performed;
a light emitting device that irradiates the processing target with first light for performing the photoelectrochemical etching;
a light emitting device that irradiates the processing target with second light that has a wavelength longer than that of the first light; and
a measurement device that measures reflected light resulting from the second light being reflected off a surface of the etch region.

2. The production apparatus for producing a structural body according to claim 1,
wherein the reflected light is scatter reflected light resulting from the second light being scatter reflected off the surface of the etch region.

3. The production apparatus for producing a structural body according to claim 1,
wherein the etch region is included in a layer made of the Group III nitride, and
wherein the measurement device measures the reflected light resulting from the second light being reflected off the surface of the etch region and reflected light resulting from the second light being reflected off a stack interface of the layer.

4. The production apparatus for producing a structural body according to claim 1,
wherein the measurement device also measures fluorescent light that is released from the etch region as a result of the processing target being irradiated with the first light.

5. A production method for producing a structural body, the production method comprising:
bringing a processing target into contact with an etching solution, the processing target including an etch region that is made of a Group III nitride, and on which photoelectrochemical etching is to be performed;
irradiating the processing target with first light for performing the photoelectrochemical etching so as to perform the photoelectrochemical etching on the etch region; and, at the same time,
irradiating the processing target with second light that has a wavelength longer than that of the first light for performing the photoelectrochemical etching so as to measure reflected light resulting from the second light being reflected off a surface of the etch region and monitor progress of the photoelectrochemical etching.

6. The production method for producing a structural body according to claim 5,
wherein the reflected light is scatter reflected light resulting from the second light being scatter reflected off the surface of the etch region.

7. The production method for producing a structural body according to claim 6,
wherein an etching depth is measured based on a pre-acquired correlation between the etching depth and an intensity of the scatter reflected light and a measured intensity of the scatter reflected light at the same time as when the photoelectrochemical etching is being performed.

8. The production method for producing a structural body according to claim 5,
wherein the etch region is included in a layer made of the Group III nitride, and
wherein in the irradiation of the processing target with the second light, the reflected light resulting from the second light being reflected off the surface of the etch region and reflected light resulting from the second light being reflected off a stack interface of the layer are measured.

9. The production method for producing a structural body according to claim 8,
wherein an etching depth is measured by calculating a thickness of the layer based on an interference pattern between the reflected light resulting from the second light being reflected off the surface of the etch region and the reflected light resulting from the second light being reflected off the stack interface of the layer at the same time as when the photoelectrochemical etching is being performed.

10. The production method for producing a structural body according to claim 9,
wherein the processing target has a stack structure that contains a Group III nitride, and
a thickness of an uppermost layer of the stack structure is measured at points in time during the photoelectrochemical etching by sequentially applying optical models that include different numbers of stacked layers as the photoelectrochemical etching progresses, the optical models being optical models based on a Fourier-transform infrared spectroscopy method, an infrared spectroscopic ellipsometry method, or an ultraviolet spectroscopic ellipsometry method.

11. The production method for producing a structural body according to claim 5,
wherein the progress of the photoelectrochemical etching is monitored by also measuring fluorescent light that is released from the etch region as a result of the processing target being irradiated with the first light.

12. The production method for producing a structural body according to claim 11,
wherein the processing target has a stack structure that contains a Group III nitride, and
the production method includes detecting, based on the fluorescent light, which layer in the stack structure is currently being subjected to the photoelectrochemical etching.
